(19) United States
(12) Patent Application Publication
(10) Pub. No.: US 2001/0034137 A1
(43) Pub. Date: Oct. 25, 2001

(54) Semiconductor device and manufacturing method of the device

(76) Inventor: Hidetaka Nambu, Tokyo (JP)

Correspondence Address: SUGHRUE, MION, ZINN,, MACPEAK & SEAS, 2100 Pennsylvania Avenue, N.W., Washington, DC, 20037, US

(21) Appl. No.: 09/836,286

(22) Filed: Apr. 18, 2001

(30) Foreign Application Priority Data
Apr. 21, 2000 (JP) 120337/2000

(51) Int. Cl. H01L 21/302; H01L 21/461

(52) U.S. Cl. 438/725; 438/706

(57) ABSTRACT

A method of manufacturing a semiconductor device having a multi-layer wiring structure including a photo-resist pattern having a prescribed opening dimension which is formed on an interlayer insulating film composed of an organic low dielectric constant film and a silicon-containing insulating film durable to an NH₃-based gas wherein the silicon-containing insulating film is dry etched using the photo-resist pattern as a mask and then the organic low dielectric constant film is etched by dry etching with NH₃ or an NH₃-containing gas using the silicon-containing insulating film as an etching mask to form an opening part having a high aspect ratio and a substantially vertical cross-section shape. The described method prevents bowing of the cross-section shape of a via hole formed in an organic low dielectric constant film as well preventing a shoulder drop effect in a silicon-containing insulating film used as an etching mask for the organic low dielectric constant film and provides a method for fabricating the semiconductor device which is capable of etching the organic low dielectric constant film with a high amount of precision.

### BACKGROUND OF THE INVENTION

1. Field of the Invention

The present invention relates to a semiconductor device and manufacturing method thereof, and particularly, but not limited to, a semiconductor device comprising via holes and grooves formed by etching an organic low dielectric constant film and manufacturing method thereof.

2. Description of the Related Art

Due to a recent tendency toward an increased level of integration of semiconductor devices and a miniaturization of chip size, a wiring structure is required to be fine and multilayered. In a semiconductor device having a multilayer wiring structure, such as LSI and the like, a concern due to a delay in the wiring caused by a parasitic capacitance between wiring patterns arises, in the case that the wiring in the multilayer wiring structure is set close together. Hence, it has become an important object to lower the wiring resistance and the wiring capacitance in order to suppress the wiring delay.

A method has been investigated for lowering wiring capacitance in a wiring structure using a material with a low dielectric constant as an interlayer insulating film, such as a hydrocarbon-based organic material and a fluorocarbon-based organic material, instead of a conventional SiO₂-based insulating film. The dielectric constants of these materials are generally in the range of 2.0 to 2.5 and their dielectric constant is approximately 40% lower than conventional SiO₂-based insulating films. Further, in order to lower the wiring resistance, a copper wire with a low resistance is generally employed instead of a conventional aluminum wiring.

In the case of forming a multilayer wiring structure using such materials, a multilayer wiring process is employed since etching of copper is difficult (as disclosed in Japanese Patent Laid-Open No. 9-55429, Japanese Patent Laid-Open No. 11-274121, Japanese Patent Laid-Open No. 2000-77409, and the like). The multilayer wiring process will be described with reference to FIG. 1A to 1H. First, as illustrated in FIG. 1A, an organic film 6a having a low dielectric constant and a silicon-containing insulating film 7a such as a silicon oxide film are formed on a silicon substrate 1. Then, as illustrated in FIG. 1B and 1C, wiring grooves 9 penetrating these insulating films 6a and 7a are formed by photolithographic and dry etching techniques using photo-resist 8a as a mask. After that a barrier metal 10a, such as tantalum nitride (TaN) or the like, is formed so as to cover the inner faces of the wiring grooves 9. A wiring metal 10b, such as Cu or the like, is then successively deposited so as to fill the wiring grooves 9. Next, a polishing process, such as a Chemical Mechanical Polishing (CMP) method, is carried out such that the barrier metal 10a and the wiring metal 10b are left only within the wiring grooves 9 to form a first wiring 10 of Cu buried in the wiring grooves 9 in the insulating layers 6a and 7a, as illustrated in FIG. 1D.

Successively, an organic low dielectric constant film 6b and a silicon-containing insulating film 7b are disposed on top of wiring layer 10 to form an upper layer of the first wiring 10 in the similar manner to FIG. 1A. Then as illustrated in Figure IF and 1 G, via holes 11 penetrating the insulating films 6a and 7b are formed by employing photolithographic and dry etching techniques. After that, a barrier metal 12a and a connection metal 12b are deposited in the via holes 11. Connection plugs 12 comprising the barrier metal 12a and the wiring metal 12b buried within the via holes 11 are formed by the CMP method, as illustrated in FIG. 1H.

In the case of forming a multilayer wiring structure in the manner as described above, the sizes of the grooves 9 and the via holes 11 may become bigger than the mask designed size creating wirings which are very close to one another. This is especially true in recent semiconductor devices based on a 0.18 μm or smaller design rule, where connection defects of wirings in the upper and lower layers are caused due to even a slight positioning difference. Consequently, etching of the interlayer insulating films is required to be carried out at a high precision; however, the organic low dielectric constant film is in general etched by Reactive Ion Etching (RIE) using oxygen gas. Etching using oxygen gas results in a problem that wiring grooves 9 and via holes 11 having high aspect ratios are difficult to form without a positioning difference.

Such a problem will be described with reference to FIG. 2. FIG. 2 is a cross-sectional view schematically showing the steps of a conventional etching method of an organic low dielectric constant film. At first, as illustrated in FIG. 2A, an organic low dielectric constant film 2 is applied to a silicon substrate 1 or a prescribed insulating film or wiring layer. As illustrated in FIG. 2B, a silicon oxide film 13 is then successively formed by a Chemical Vapor Deposition (CVD) method. After that, as illustrated in FIG. 2C, a photo-resist pattern 4 having prescribed opening parts 5 is formed on the silicon oxide film 13 by employing a well known lithographic technique.

Next, as illustrated in FIG. 2D, the silicon oxide film 13 is etched by a fluorine-based gas, such as CF₄ or the like, using the photo-resist pattern 4 as an etching mask. Then, as illustrated in FIG. 2E, the organic low dielectric constant film 2 is etched by dry etching with oxygen gas using the silicon oxide film 13 as an etching mask. In this case, in order to sufficiently assure the isotropy of the dry etching, the pressure of the oxygen gas should be lowered and the self-bias voltage (Vdc) has to be high. In such conditions, a sufficiently high etching rate cannot generally be obtained owing to the decrease of the concentration of the radical nuclei which perform etching. On the other hand, if the radical concentration is increased in order to improve the etching rate, the isotropic property can not be obtained and, as illustrated FIG. 2E, the inner wall of a via hole is curved into a bow shape. If a via hole is formed in a shape, portions where no barrier metal is formed are caused, and voids occurring in the via hole result in deterioration of the reliability of the connection at the time when a metal film is buried in the via hole.

Further, if oxygen gas is used, such as etching with an oxygen plasma, the dielectric constant of the surface layer is increased owing to the formation of C-O bond on the surface of the organic low dielectric constant film 2, resulting in the effect of using a low dielectric constant film being lowered.

As described above, by dry etching with oxygen gas, it is difficult to carry out etching vertically to form a via hole of the mask-designed size. Since the over etching margin is narrow in recent semiconductor devices requiring fine wiring, dry etching using oxygen gas is difficult to employ for the fabrication of such a semiconductor device without further narrowing the over etching margin.

Therefore, a method is suggested to use N₂/H₂ gas instead of oxygen gas as an etching gas. This method will be described with reference to FIG. 3.

First, as illustrated in FIG. 3A, an organic low dielectric constant film 2 is applied to a silicon substrate 1 or a prescribed insulating film or wiring layer and, as illustrated in FIG. 3B, a silicon oxide film 13 is formed thereon. After that, as illustrated in FIG. 3C, a photo-resist pattern 4 having prescribed opening parts S is formed on the silicon oxide film 13 by employing a well known lithographic technique and using the photo-resist pattern 4 as a mask. As illustrated in FIG. 3D, the silicon oxide film 13 is etched by a fluorine-based gas such as CF₄ or the like. Successively, as shown in FIG. 3E, the organic low dielectric constant film 2 is etched with N₂/H₂ gas using the etched silicon oxide film 13 as an etching mask.

In the case where etching of the organic low dielectric constant film 2 is carried out using N₂/H₂ gas, reaction products containing C—N bonds are produced in the side walls of the etched hole of the organic low dielectric constant film 2, so that excess etching of the side walls of a via hole can be prevented. Consequently, the etching cross-section does not become curved into a bow shape and the margin for over etching is kept wide (not further narrowed).

However, since N₂/H₂ gas has a low etching rate and takes a long etching time, productivity is diminished. Also, since it takes long for the etching with N₂/H₂ gas, the time to sputter the silicon oxide film 13 using as a hard mask is prolonged resulting in a problem, a so-called shoulder drop, wherein the opening cross-section of the silicon oxide film 13 is shifted outward and the opening dimension is widened.

The present invention is developed taking the above described problems into consideration. One of the main purposes of the present invention is to provide a semiconductor device and a manufacturing method thereof, wherein an organic low dielectric constant film can be etched with high precision without forming a bow-shaped cross-section of a via hole formed in the organic low dielectric constant film, or causing shoulder drop of a silicon-containing insulating film employed as an etching mask for the organic low dielectric constant film.

### SUMMARY OF THE INVENTION

In order to achieve the foregoing, according to an embodiment of the present invention, etching of an interlayer insulating film of an organic low dielectric constant film is carried out using NH₃ or an NH₃-containing gas.

Further, the embodiment of the present invention provides an insulating film etching method for carrying out etching by forming a photo-resist pattern on an interlayer insulating film composed of an organic low dielectric constant film and a silicon-containing insulating film formed thereon, etching the silicon-containing insulating film using the photo-resist pattern as a mask, and then etching the organic low dielectric constant film using the silicon-containing insulating film as a mask. Etching of the organic low dielectric constant film is carried out using NH₃ or an NH₃-containing gas and the photo-resist pattern is simultaneously removed at the time of etching the organic low dielectric constant film.

Further, the present invention provides a method for fabricating a semiconductor device having a multilayer wiring structure comprising at least a step of forming an organic low dielectric constant film with a prescribed film thickness on an upper layer of a semiconductor substrate, a step of depositing a silicon-containing insulating film on the organic low dielectric constant film, a step of forming a photo-resist pattern having prescribed openings on the silicon-containing insulating film, a step of etching the silicon-containing insulating film by dry etching with a fluorine-based gas using the photo-resist pattern as a mask, a step of forming through-holes with prescribed shapes by etching the organic low dielectric constant film using the silicon-containing insulating film as a mask, and a step of burying a barrier metal and a wiring metal film within the through-holes, where the etching of the organic low dielectric constant film is carried out using NH₃ or an NH₃-containing gas and the photo-resist pattern is simultaneously removed at the time of etching the organic low dielectric constant film.

The semiconductor device of the present embodiment is a semiconductor device having a multilayer wiring structure comprising at least an interlayer insulating film formed on an upper layer of a substrate, composed of an organic low dielectric constant film with a prescribed film thickness, a silicon-containing insulating film durable to an NH₃-based gas, through-holes with prescribed shapes formed in the interlayer insulating film, a wiring layer formed by burying a barrier metal and a wiring metal film within the through-holes, the through-holes formed in the organic low dielectric constant film by dry etching with NH₃ or an NH₃-containing gas and having an aspect ratio of a prescribed value or higher.

In the present embodiment, the foregoing NH₃-containing gas is a gas mixture of NH₃ mixed with at least one of N₂, H₂ and O₂. The foregoing silicon-containing insulating film including at least one of SiO₂, SiN, SiC, SiOF, an organic SOG, an inorganic porous film, or an inorganic low dielectric constant film. The foregoing organic low dielectric constant film preferably comprises a silicon-free organic film, a hydrocarbon-based organic low dielectric constant film, an aromatic-based organic low dielectric constant film, or a fluorine-containing resin film.

As described above, the present embodiment describes etching of an organic low dielectric constant film within an interlayer insulating film having a double layer structure composed of an organic low dielectric constant film and a silicon-containing insulating film durable to an NH₃-based gas. Etching of the silicon-containing insulating film is accomplished using a photo-resist pattern as a mask, and then etching the organic low dielectric constant film with NH₃ or an NH₃-containing gas using the silicon-containing insulating film as a mask, so that the shoulder drop of the silicon-containing insulating film can be prevented. Through-holes with an approximately vertical cross-sectional shape and the same opening diameter as the openings of the photo-resist pattern are thus formed, and further, as compared with the etching rate using a N₂/H₂ gas, the etching rate can be increased, so that the etching time can be shortened.

### BRIEF DESCRIPTION OF THE DRAWINGS

FIG. 1A is a cross-sectional view schematically illustrating a step of an etching method of an organic low dielectric constant film relevant to the related art.

FIG. 1B is a cross-sectional view schematically illustrating a step of an etching method of an organic low dielectric constant film relevant to the related art.

FIG. 1C is a cross-sectional view schematically illustrating a step of an etching method of an organic low dielectric constant film relevant to the related art.

FIG. 1D is a cross-sectional view schematically illustrating a step of an etching method of an organic low dielectric constant film relevant to the related art.

FIG. 1E is a cross-sectional view schematically illustrating a step of an etching method of an organic low dielectric constant film relevant to the related art.

FIG. 1F is a cross-sectional view schematically illustrating a step of an etching method of an organic low dielectric constant film relevant to the related art.

FIG. 1G is a cross-sectional view schematically illustrating a step of an etching method of an organic low dielectric constant film relevant to the related art.

FIG. 1H is a cross-sectional view schematically illustrating a step of an etching method of an organic low dielectric constant film relevant to the related art.

FIG. 2A is a cross-sectional view schematically showing a problem of a conventional etching method of an organic low dielectric constant film.

FIG. 2B is a cross-sectional view schematically showing a problem of a conventional etching method of an organic low dielectric constant film.

FIG. 2C is a cross-sectional view schematically showing a problem of a conventional etching method of an organic low dielectric constant film.

FIG. 2D is a cross-sectional view schematically showing a problem of a conventional etching method of an organic low dielectric constant film.

FIG. 2E is a cross-sectional view schematically showing a problem of a conventional etching method of an organic low dielectric constant film.

FIG. 3A is a cross-sectional view schematically showing a problem of a conventional etching method of an organic low dielectric constant film.

FIG. 3B is a cross-sectional view schematically showing a problem of a conventional etching method of an organic low dielectric constant film.

FIG. 3C is a cross-sectional view schematically showing a problem of a conventional etching method of an organic low dielectric constant film.

FIG. 3D is a cross-sectional view schematically showing a problem of a conventional etching method of an organic low dielectric constant film.

FIG. 3E is a cross-sectional view schematically showing a problem of a conventional etching method of an organic low dielectric constant film.

FIG. 4A is a cross-sectional view schematically illustrating a fabrication method of a semiconductor device of a multilayer wiring structure relevant to a first example of the present invention.

FIG. 4B is a cross-sectional view schematically illustrating a fabrication method of a semiconductor device of a multilayer wiring structure relevant to a first example of the present invention.

FIG. 4C is a cross-sectional view schematically illustrating a fabrication method of a semiconductor device of a multilayer wiring structure relevant to a first example of the present invention.

FIG. 4D is a cross-sectional view schematically illustrating a fabrication method of a semiconductor device of a multilayer wiring structure relevant to a first example of the present invention.

FIG. 4E is a cross-sectional view schematically illustrating a fabrication method of a semiconductor device of a multilayer wiring structure relevant to a first example of the present invention.

FIG. 5A is a cross-sectional view schematically illustrating a fabrication method of a semiconductor device of a multilayer wiring structure relevant to a second example of the present invention.

FIG. 5B is a cross-sectional view schematically illustrating a fabrication method of a semiconductor device of a multilayer wiring structure relevant to a second example of the present invention.

FIG. 5C is a cross-sectional view schematically illustrating a fabrication method of a semiconductor device of a multilayer wiring structure relevant to a second example of the present invention.

FIG. 5D is a cross-sectional view schematically illustrating a fabrication method of a semiconductor device of a multilayer wiring structure relevant to a second example of the present invention.

FIG. 5E is a cross-sectional view schematically illustrating a fabrication method of a semiconductor device of a multilayer wiring structure relevant to a second example of the present invention.

FIG. 5F is a cross-sectional view schematically illustrating a fabrication method of a semiconductor device of a multilayer wiring structure relevant to a second example of the present invention.

FIG. 5G is a cross-sectional view schematically illustrating a fabrication method of a semiconductor device of a multilayer wiring structure relevant to a second example of the present invention.

FIG. 5H is a cross-sectional view schematically illustrating a fabrication method of a semiconductor device of a multilayer wiring structure relevant to a second example of the present invention.

### BRIEF DESCRIPTION OF THE PREFERRED EMBODIMENTS

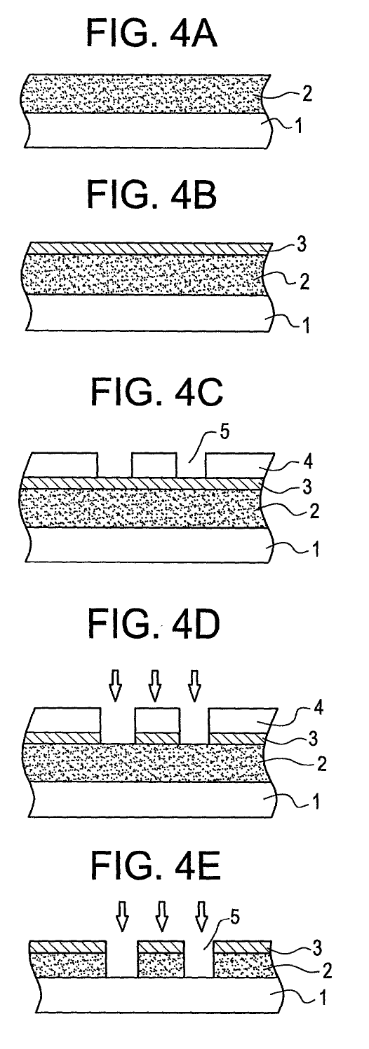

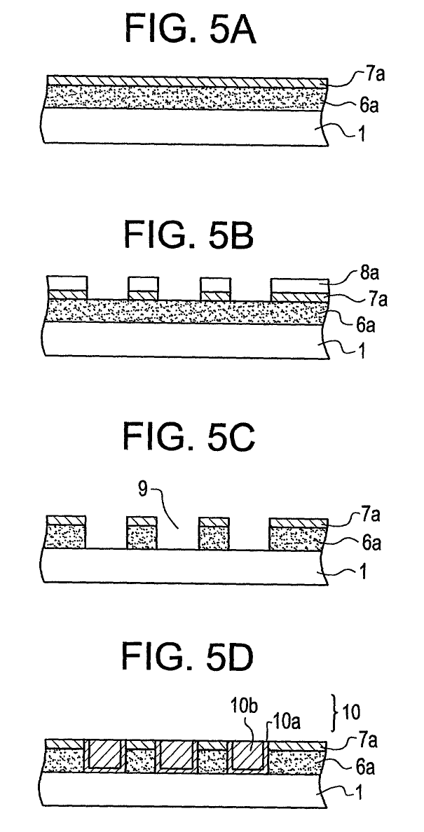

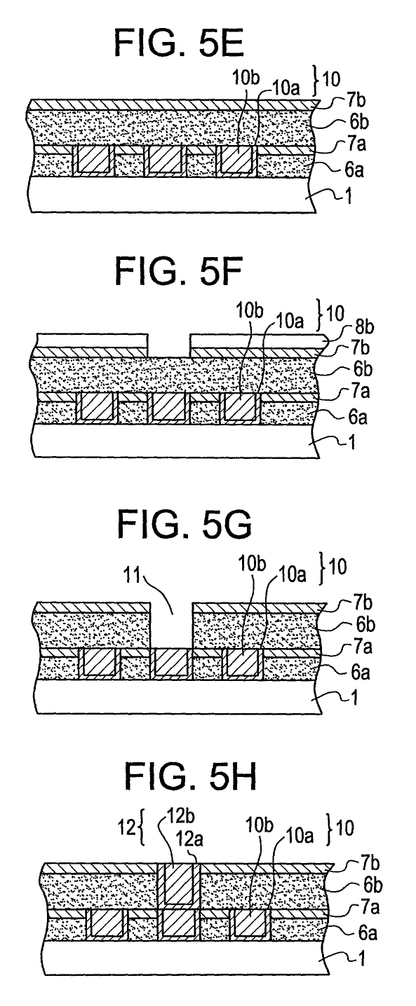

Regarding an etching method of an organic low dielectric constant film relevant to the present invention, one preferred embodiment is to form opening parts 5 (FIG. 4) with a high aspect ratio and an approximately vertical cross-section shape. This is accomplished by providing wiring grooves 9 (FIG. 5), and at least one via hole 11 (FIG. 6) with a high degree of precision by forming a photo-resist pattern 4 (FIG. 4) having a prescribed opening dimension on an interlayer insulating film which is composed of an organic low dielectric constant film 2 (FIG. 4) and a silicon-containing insulating film 3 (FIG. 4) having durability to an NH₃-based gas. The silicon-containing insulating film is then dry-etched using the photo-resist pattern as a mask, and the organic low dielectric constant film is then dry-etched with NH₃ or an NH₃-containing gas using the silicon-containing insulating film as an etching mask.

To describe the foregoing embodiment of the present invention in further detail, examples of the present invention will be described with reference to FIGS. 4 and 5.

First, an etching method of an organic low dielectric constant film relevant to a first example of the present invention will be described with reference to FIG. 4. FIG. 4 is a cross-sectional view schematically illustrating the steps of the etching method of an organic low dielectric constant film embodied in one aspect of the present invention.

As shown in FIG. 4, the etching method of this example provides a substantially vertical etching of an organic low dielectric constant film with high precision. An organic low dielectric constant film 2 comprising, for example, a hydrocarbon-based organic film, an aromatic-based organic film or a fluorine-containing resin film, and having a thickness of about 0.2 to 0.4 μm, is applied by spin coating to a silicon substrate 1 or an insulating film or a wiring layer formed thereon. Then, as illustrated in FIG. 4B, a silicon-containing insulating film 3 comprising, for example, a general inorganic filn, an inorganic low dielectric constant film, an inorganic porous film, an organic SOG (Spin On Glass) film and the like, having a thickness of about 0.1 to 0.2 μm, is deposited on the organic low dielectric constant film by a CVD method or the like.

Examples of the hydrocarbon-based organic low dielectric constant film 2 to be employed may be ALCAP (trade name) produced by Asahi Chemical Industry Co., Ltd., VELOX (trade name) produced by Schumacher Co., SiLK (trade name) produced by Dow Chemical Co., and so forth. Examples of the aromatic-based organic low dielectric constant film 2 to be employed are SiLK (trade name) produced by Dow Chemical Co., FLARE (trade name) produced by Allied Signal Co., Ltd., and so forth. Further, usable examples of the inorganic film may be SiO₂, SiN, SiC, SiOF, and so forth. Examples of the inorganic low dielectric constant film may include HSQ (Hydrogen Silisesquioxane) and so forth. Examples of the inorganic porous film may be nanoglass (trade name) and so forth, and examples of the organic SOG film may include MSQ and the like of HOSP (trade name) and so forth. Incidentally, a low dielectric constant material preferably is used in the case where the silicon-containing insulating film 3, which is used as a hard mask, is left as an interlayer insulating film after etching of the organic low dielectric constant film 2.

Next, as illustrated in FIG. 4C, a photo-resist pattern 4 having prescribed openings is formed on the silicon-containing insulating film 3 by a well known lithographic technique. As illustrated in FIG. 4D, the silicon-containing insulating film 3 is etched by dry etching with a fluorine-based gas, for example, C₄F₈/Ar/O₂ and the like, using the photo-resist pattern 4 as a mask. Successively, as illustrated in FIG. 4E, the organic low dielectric constant film 2 is dry etched using, for example, NH₃ gas or an NH₃ gas mixture containing another gas and using the patterned silicon-containing insulating film 3 as an etching mask. At that time, the photo-resist pattern 4 formed on the silicon-containing insulating film 3 is simultaneously removed with the etching of the organic low dielectric constant film 2, such that there is no need to remove the photo-resist pattern 4 prior to etching the organic low dielectric constant film.

Additional examples of the fluorine-based gas employed for etching of the silicon-containing insulating film 3 include CF₄, CF₄/Ar, C₄F₈/Ar, and the like in addition to C₄FAr/O₂ gas. Additional examples of the gas employed for etching the organic low dielectric constant film 2 include NH₃/N₂, NH₃/H₂, NH₃/N₂/H₂, NH₃/O₂, and the like, in addition to the NH₃ gas.

In this case, by using an NH₃-containing gas, NH produced by isolation from the mother gas can be increased to increase the etching rate. Consequently, the etching time of the silicon-containing insulating film 3, which is used as a hard mask, can be shortened. Thus, the shoulder drop of the silicon-containing insulating film 3 can be prevented. Further, since NH₃ is easily isolated to increase electron density, the self-bias voltage to the silicon substrate 1 can be lowered and the resulting etching efficiency during production of the hard mask can further be decreased.

Further, by mixing NH₃ gas with any one of N₂, H₂, and O₂ gases, or these gases in combination, the etching rate can be increased and the margin for over etching is widened (and thereby may further be reduced). The combination and the mixing ratio of the gases may be easily determined for the optimum conditions in relation to an object to be etched.

As described above, the shoulder drop of the silicon-containing insulating film is prevented and through-holes having the same opening dimensions as those of the openings of the photo-resist pattern 4 are formed in accordance with this embodiment of the present invention. Further, as compared with the etching rate using a N₂/H₂ gas, the etching rate is increased, especially by making an interlayer insulating film having a double layer structure composed of an organic low dielectric constant film 2 and a silicon-containing insulating film 3, which is preferably an inorganic low dielectric constant film. By etching the silicon-containing insulating film 3 using the photo-resist pattern 4, and then etching the organic low dielectric constant film 2 with an NH₃-containing gas using the silicon-containing insulating film 3 as a mask, the resulting etching time can be further shortened.

Further, since the etching efficiency of the silicon-containing insulating film 3 is lowered, the silicon-containing insulating film 3 can be made thin and the dielectric constant of the entire body of the interlayer insulating film can be lowered. Also, opening parts 5 having a high aspect ratio and an etched cross-sectional shape which is approximately vertical can be formed. For example, opening parts S with an aspect ratio of 1.5 or higher can be formed by controlling the film thickness of the silicon-containing insulating film 3 to be about 0.3 μm or thinner, preferably 0.1 to 0.2 μm, and the film thickness of the organic low dielectric constant film 2 to be 0.1 μm or thicker, preferably 0.2 to 0.4 μm, and the opening diameter of the photo-resist pattern 4 to be about 0.2 μm.

Although this example is described for a case where an organic low dielectric constant film 2 and a silicon-containing insulating film 3 are formed on the silicon substrate 1 then etched, the present invention is not restricted to the above described example and is applicable for any case where it is desired to lower the parasitic capacitance between wirings using an organic low dielectric constant film 2, and further, to other organic films containing no silicon which can be employed as the organic low dielectric constant film 2.

Next, a semiconductor device and the method of manufacturing such a semiconductor device with respect to a second aspect of the present invention will be described with reference to FIG. 5. FIGS. 5A to 5E are cross-sectional views schematically illustrating the fabrication steps of the semiconductor device relevant to the second embodiment of the present invention. This aspect of the invention involves employing the etching method of the organic low dielectric constant film of the first embodiment for a semiconductor device of a multilayer wiring structure.

With reference to FIG. 5A to 5E, the manufacturing method of the semiconductor device of this example will be described. First, as illustrated in FIG. 5A, which is the same as the foregoing example, an organic low dielectric constant film 6a, for example: a hydrocarbon-based organic insulating material, an aromatic-based organic insulating material, a fluorine-containing resin, or the like, having a thickness of about 0.2 to 0.4 μm, is formed on a silicon substrate 1. The organic low dielectric constant film may also be formed on an insulating film such as a silicon oxide film, a silicon nitride film, or the like, or a prescribed wiring layer formed thereon by a spin coating or CVD method. Then, successively, a silicon-containing insulating film 7a such as an inorganic low dielectric constant film of HSQ or the like, an inorganic film of SiN or the like, an inorganic porous film, or an organic SOG having a thickness of about 0.1 to 0.2 μm is deposited by a CVD or spin coating method.

After that, as illustrated in FIG. 5B, a photo-resist pattern 8a having prescribed openings is formed on the silicon-containing insulating film 7a by employing a well known lithographic technique.

Then, using the photo-resist pattern 8a as a mask, the silicon-containing insulating film 7a is etched by a dry etching process. In the case where SiN is used for the silicon-containing insulating film 7a, the following etching conditions are used. For example, CF/Ar/O₂ is used as an etching gas, and the flow rate is controlled to be CF₄/Ar/O₂=30/150/15 sccm, with a pressure of 15 mTorr (2.0 pa), and a bias power of 400 W.

As illustrated in FIG. 5C, using the silicon-containing insulating film 7a as an etching mask, the organic low dielectric constant film 6a is dry etched. In the case where SiLK is used as the organic low dielectric constant film 6a, the etching conditions are as follows. For example, etching of the film is carried out using NH₃ gas or an NH₃ gas mixture containing N₂, H₂, or O₂ as the etching gas.

In this case, by using an NH₃-containing gas, as in the first embodiment, NH conductive to etching can be increased and the self-bias voltage to the silicon substrate 1 can be lowered, so that the time for etching the silicon-containing insulating film 7a to form a hard mask can be shortened, and the shoulder drop of the silicon-containing insulating film 7a can be prevented.

Next, as illustrated in FIG. 5D, a barrier metal 10a of Ta or TaN, for example, and a wiring metal 10b of such as Cu, for example, are deposited to cover the inner faces of the wiring grooves 9. This may be accomplished by, for example, sputtering the barrier metal 10a, and then forming the wiring metal 10b by an electroplating method. After that, annealing is carried out in a hydrogen gas atmosphere to improve the reflow of the wiring metal 10b. Next, polishing is carried out using, for example, a CMP method which leaves the barrier metal 10a and the wiring metal 10b only inside the wiring grooves 9 to form a first wiring (wiring layer) 10 as illustrated in FIG. 5D.

Though the width of the wiring grooves 9 and the gap there between are as thin as about 0.2 μm, respectively in this example, short circuits and positioning differences do not take place in the wiring, since etching can be carried out precisely to the mask size by the etching method of this example. Further, the side walls of the wiring grooves 9 are etched to have an approximately vertical cross-section, and unlike those wiring grooves etched by oxygen gas in a conventional example, the side walls are not formed to be a bowing shape, so that voids formed in the wiring grooves 9 can be avoided.

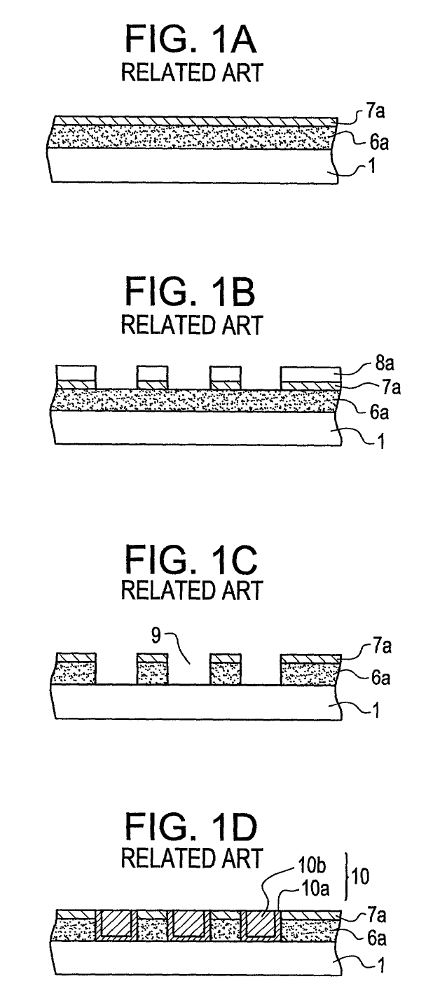

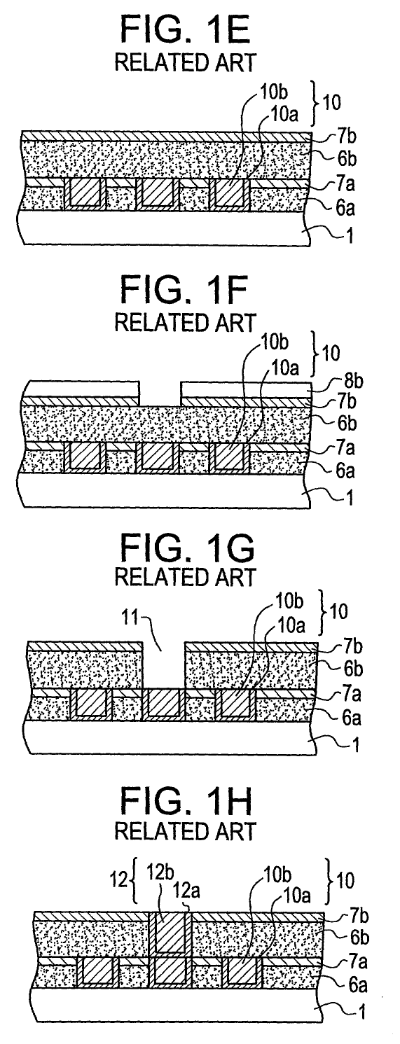

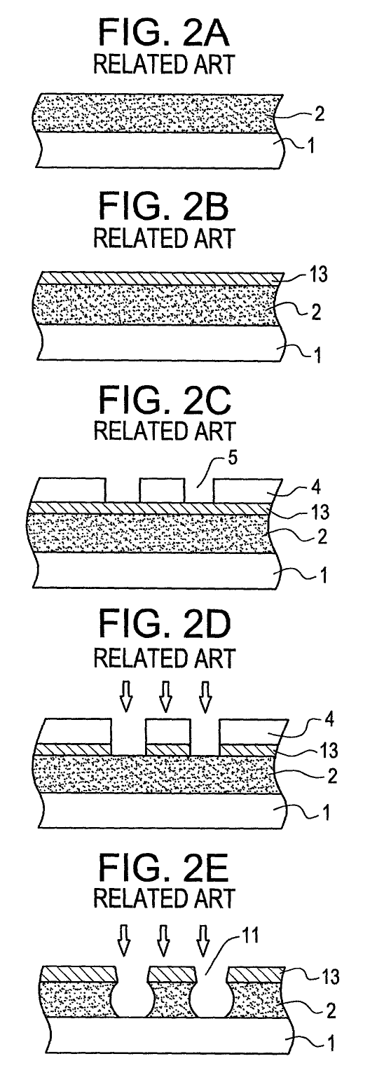

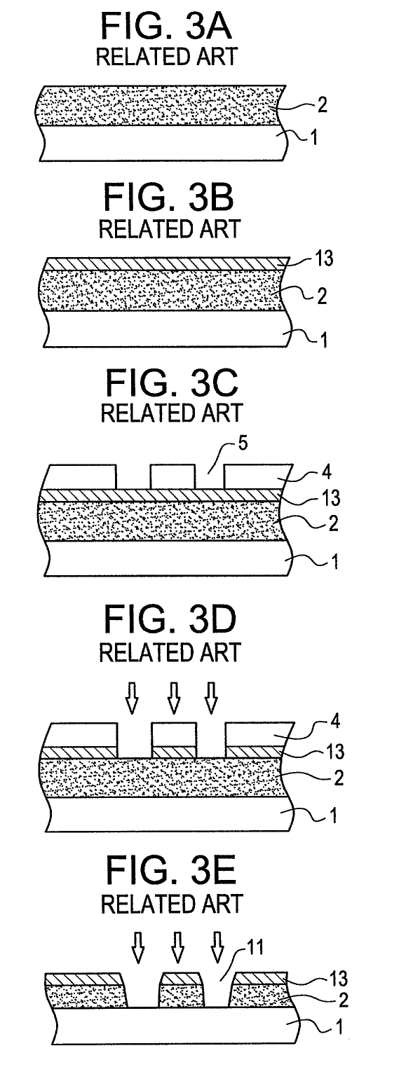

Next, a prescribed wiring plug 12 is formed on the first wiring 10. The procedure for forming the wiring plug 12 is similar to that shown in FIGS. 1E to 1H, except that the type, the thickness, and etching conditions of the film to be formed differ. First, as illustrated in Figure SE, an organic low dielectric constant film 6a of, for example, a hydrocarbon-based, an aromatic-based, or a fluorine-containing resin is formed to a thickness of 0.2 to 0.4 μm on the first wiring 10. Then, the silicon-containing insulating film 7a is formed by a spin coating or CVD method. Then, successively, a silicon-containing insulating film 7b of, for example, an inorganic low dielectric constant film, an inorganic film of SiO₂ or the like, an inorganic porous film, or an organic SOG film is deposited to a thickness of 0.1 to 0.2 μm by a CVD or spin coating method. After that, a photoresist pattern 8a having openings in parts where connection plug holes 12 are to be formed is formed by employing a well known lithographic technique.

Then, as illustrated in FIG. 5F, the silicon-containing insulating film 7b is dry etched with a fluorine-based gas using the photo-resist pattern 8b as a mask. Then, as illustrated in FIG. 5G, the organic low dielectric constant film 6b is etched by dry etching with NH₃ or an NH₃ gas mixture containing N₂, H₂, or O₃ using the silicon-containing insulating film 7b as a mask. In the case where SiO₂ gas is used to form the silicon-containing insulating film 7a, the etching conditions are, for example, as follows: CF /Ar/O₂ is used as the etching gas, the flow rate is controlled such that CF₄/Ar/O₂=30/150/15 sccm, the pressure is 15 mTorr (2.0 pa), and bias power is 400 W. In the case where SiLK is used for the organic low dielectric constant film 6b, for example, the etching is preferably carried out using NH₃ gas, at a 600 sccm flow rate, with 300 mTorr (40 pa) pressure, and a 1,200 W bias power.

The film thickness of the organic low dielectric constant film 6b is made thicker than that of the organic low dielectric constant film 6a in order to smooth and flatten other roughened regions (not shown) and in spite of this, the aspect ratio of the via holes 11 is high even though the film thickness of the organic low dielectric constant film 6a is thick, and the via holes 11 are formed substantially vertically by using NH₃ or an NH₃-containing gas in this example, so that the design margin can be maintained (kept wide).

Afterwards, as illustrated in FIG. 5H, a barrier metal 12a and a connection metal 12b such as Cu are deposited to cover the inner faces of the via holes 11 by, for example, a sputtering method and then polishing is carried out by a CMP method such that the barrier metal 12a and the connection metal 12b are only left inside of the via holes 11 to form connection plugs 12 connected with prescribed first wiring 10. By forming subsequent wiring layers in the same manner, a semiconductor device having a multilayer wiring structure can be fabricated.

As described above, in the manufacturing of a semiconductor device having a multilayer wiring structure, as in the first example, the low dielectric constant film is formed to have a double layer structure composed of organic low dielectric constant films 6a, 6b and a silicon-containing insulating film 7a, 7b, and after the silicon-containing insulating film 7a, 7b is etched with a fluorine-based gas using a photo-resist pattern 8a, 8b as a mask, the organic low dielectric constant film 6a, 6b is etched with NH₃ or an NH₃-containing gas using the silicon-containing insulating film 7a, 7b as a mask. Therefore, the shoulder drop of the silicon-containing insulating film 7a, 7b due to etching can be prevented, and wiring grooves 9 and via holes 11 can be formed to have the opening dimensions which are the same as that of the openings of the photo-resist pattern 8a, 8b. Also the etching time of the organic low dielectric constant films can be shortened since the etching rate is high compared with that in the case of etching with N₂/H₂ gas.

Similarly, as in the first example, the same gases are usable as for etching the organic low dielectric constant film 2, these include NH₃/N₂, NH₃/H₂, NH₃/O₂, and their combinations, as well as solely NH₃ gas. Films, usable as the silicon-containing insulating film, include inorganic films of SiO₂, SiN, SiC, SiOF, and the like, inorganic low dielectric constant films of HSQ and the like, organic SOG films of MSQ and the like. Films usable as the organic low dielectric constant film include other organic films containing no Si.

As described above, the semiconductor device and its manufacturing method of the present invention can provide the following advantages.

A first advantage of the present invention is that an organic low dielectric constant film of a hydrocarbon-based, an aromatic-based or a fluorine-containing resin can be etched with high precision having the same size as the mask designed size. That is, because etching can be carried out in such a manner that the shoulder drop due to etching of a silicon-containing insulating film is prevented, forming a substantially vertical cross-section shape. This is accomplished by forming the silicon-containing insulating film on the organic low dielectric constant film, etching the silicon-containing insulating film using a photo-resist pattern as a mask, and then etching the organic low dielectric constant film with NH₃ or an NH₃-containing gas using the silicon-containing insulating film as a mask.

Further, a second advantage of the present invention is that the etching time can be shortened as compared with the case of etching with N₂/H₂ gas, and thus, throughput can be improved. That is, because the amount of NH isolated from a mother gas can be increased by using NH₃ or an NH₃-containing gas, and thus, the etching rate can be increased.

The present invention is not limited to the above embodiments, and it is contemplated that numerous modifications may be made without departing from the spirit and scope of the invention. The manufacturing method, as described above with reference to the drawings, is a merely an exemplary embodiment of the invention, and the scope of the invention is not limited to these particular embodiments. Accordingly, other structural configurations and other materials may be used, without departing from the spirit and scope of the invention as defined in the following claims.

What is claimed is:

1. A method of etching an insulating film comprising the step of:
etching an interlayer insulating film comprised of an organic low dielectric constant film using a gas comprising NH₃.

2. A method of manufacturing a semiconductor device, comprising the steps of:
forming an organic low dielectric constant film on a substrate;
forming a silicon-containing insulating film on said organic low dielectric constant film;
removing a part of said silicon-containing insulating film to form a first opening; and
etching said organic low dielectric constant film using said silicon-containing insulating film with said first opening as a first mask;
wherein said step of etching said organic low dielectric constant film is carried out using a gas comprising NH₃.

3. The method of manufacturing a semiconductor device as claimed in claim 2, wherein said gas comprising NH₃ additionally comprises at least one of N₂, H₂ and O₂.

4. The method of manufacturing a semiconductor device as claimed in claim 3, wherein said silicon-containing insulating film comprises one of SiO₂, SiN, SiC, SiOF, an organic SOG, an inorganic porous film, and an inorganic low dielectric constant film.

5. The method of manufacturing a semiconductor device as claimed in claim 3, wherein said organic low dielectric constant film comprises at least one of a silicon-free organic film, a hydrocarbon-based organic low dielectric constant film, an aromatic-based organic low dielectric constant film, and a fluorine-containing resin film.

6. The method of manufacturing a semiconductor device as claimed in claim 3, further comprising steps of:
forming a photo-resist on said silicon-containing insulating film; and
removing a part of said photo-resist to form a second opening,
wherein said step of removing a part of said silicon-containing insulating film is carried out using said photo-resist with said second opening as a second mask, and
wherein said photo-resist is removed during said step of etching said organic low dielectric constant film.

7. The method of manufacturing a semiconductor device as claimed in claim 6, wherein an aspect ratio is higher than 1.5,
wherein the aspect ratio is given by a sum of a thickness of said organic low dielectric constant film and a thickness of said silicon-containing insulating film divided by a width dimension of said first opening.

8. The method of manufacturing a semiconductor device as claimed in claim 7, wherein said thickness of said organic low dielectric constant film is greater than 0.1 micrometers.

9. The method of manufacturing a semiconductor device as claimed in claim 7, wherein said thickness of said silicon-containing insulating film is less than 0.3 micrometers.

10. The method of manufacturing a semiconductor device as claimed in claim 7, wherein said width dimension of said second opening is approximately but not less than 0.2 micrometers.

11. A method of manufacturing a semiconductor device, comprising the steps of:
forming a first organic low dielectric constant film on a substrate;
forming a first silicon-containing insulating film on said organic low dielectric constant film;
removing a portion of said first silicon-containing insulating film to form a first opening;
etching said first organic low dielectric constant film using said first silicon-containing insulating film with said first opening as a first mask in order to form at least one through-hole penetrating said first organic low dielectric constant film and said first silicon-containing insulating film;
forming a first barrier metal on an entire inside surface of said at least one through-hole;
forming a first connection metal film on said first barrier metal film, so as to fill said at least one through-hole,
wherein said step of etching said first organic low dielectric constant film is carried out using a gas comprising NH₃.

12. The method of manufacturing a semiconductor device as claimed in claim 11, wherein said gas comprising NH₃ additionally comprises at least one of N₂, H₂ and O₂.

13. The method of manufacturing a semiconductor device as claimed in claim 12, wherein said first silicon-containing insulating film comprises one of SiO₂, SiN, SiC, SiOF, an organic SOG, an inorganic porous film, and an inorganic low dielectric constant film.

14. The method of manufacturing a semiconductor device as claimed in claim 12, wherein said first organic low dielectric constant film comprises at least one of a silicon-free organic film, a hydrocarbon-based organic low dielectric constant film, an aromatic-based organic low dielectric constant film, and a fluorine-containing resin film.

15. The method of manufacturing a semiconductor device as claimed in claim 12, further comprising steps of:
forming a photo-resist on said silicon-containing insulating film; and
removing a portion of said photo-resist to form a second opening,
wherein said step of removing a portion of said first silicon-containing insulating film is carried out using said photo-resist with said second opening as a second mask, and
wherein said photo-resist is removed during said step of etching said first organic low dielectric constant film.

16. The method of manufacturing a semiconductor device as claimed in claim 15, wherein an aspect ratio is higher than 1.5, wherein the aspect ratio is given by a sum of a thickness of said first organic low dielectric constant film and a thickness of said first silicon-containing insulating film divided by a width dimension of said first opening.

17. The method of manufacturing a semiconductor device as claimed in claim 16, further comprising steps of:
forming a second organic low dielectric constant film on said first silicon-containing insulating film and said first connection metal film formed on said first organic low dielectric constant film;
forming a second silicon-containing insulating film on said second organic low dielectric constant film;
removing a portion of said second silicon-containing insulating film to form a third opening; and
etching said second organic low dielectric constant film using said second silicon-containing insulating film with said third opening as a third mask in order to form at least a second through-hole penetrating said second organic low dielectric constant film and said second silicon-containing insulating film;
wherein said step of etching said second organic low dielectric constant film is carried out using a gas comprising NH₃.

18. The method of manufacturing a semiconductor device as claimed in claim 17, wherein said gas comprising NH₃ additionally comprises at least one of N₂, H₂ and O₂.

19. The method of manufacturing a semiconductor device as claimed in claim 18, further comprising steps of:
forming a second barrier metal film on an entire inside surface of said at least second through-hole interconnected with said first connection metal film and said first barrier metal film;
forming a second connection metal film on said second barrier metal film, so as to fill said at least second through-hole.

20. A semiconductor device having a multilayer wiring structure, comprising:
a substrate;
an interlayer insulating film comprising an organic low dielectric constant film disposed on the substrate and a silicon-containing insulating film disposed on said organic low dielectric constant film; and
a through-hole formed in said interlayer insulating film;
wherein said through-hole is formed by dry etching with a gas comprising NH₃ and has an aspect ratio that is larger than 1.5.
